(19) United States
(12) Patent Application Publication
(10) Pub. No.: US 2008/0251933 A1
(43) Pub. Date: Oct. 16, 2008

(54) METAL INTERCONNECT STRUCTURE

(76) Inventors: Kuo-Yao Cho, Taichung County (TW); Wen-Bin Wu, Tao-Yuan Hsien (TW); Chiang-Lin Shih, Taipei Hsien (TW); Chia-Cheng Lin, Chiayi County (TW)

Correspondence Address: NORTH AMERICA INTELLECTUAL PROPERTY CORPORATION, P.O. BOX 506, MERRIFIELD, VA, 22116, US

(21) Appl. No.: 11/845,746

(22) Filed: Aug. 27, 2007

(30) Foreign Application Priority Data
Apr. 10, 2007 (TW) 096112468

(51) Int. Cl. H01L 23/525; H01L 23/52

(52) U.S. Cl. 257/775; 257/E23.168

(57) ABSTRACT

A metal interconnect structure includes a plurality of first plugs adjacent to each other, a first metal line extending in a first direction and contacting each first plug to form a first section with a tapered second section in between, and a second plug adjacent to the second section, both in a second direction normal to the first direction.

### BACKGROUND OF THE INVENTION

1. Field of the Invention

The present invention relates to a metal interconnect structure. More particularly, the present invention relates to a metal interconnect structure which avoids short circuiting.

2. Description of the Prior Art

With the increasing packing density of the IC elements, especially for the manufacturing of the DRAM, the pitch of the critical dimension elements, the metal interconnect structure in particular, decreases as well. FIG. 1 illustrates the layout of the metal interconnect structure in the DRAM of the prior art. As shown in FIG. 1, a plurality of parallel metal interconnects 11 and 11′ which are separated by insulation layer 12 to avoid short circuiting, are in the layout 10 of the metal interconnect structure in the DRAM. There are metal plugs 13, 13′ and 13″ under the metal interconnect 11 and directly contacting the metal interconnect 11, usually serving as the electrical connection of the source/drain underneath. In order to decrease the resistance, the width of the metal plugs is usually greater than that of the metal interconnect 11. Between the metal plug 13 and 13′ there is a metal region 14 under another neighboring metal interconnect 11′. The distance between the metal region 14 and the metal plug 13 is P.

The dimension of many elements, such as the pitch P, shrinks with the shrinkage of the critical dimension. The pitch P would be too small to maintain the insulation between the metal region 14 and the metal plug 13 when technical errors occur, such as the misalignment of the reticle on dense patterns. Nevertheless, in order to increase the contact area, it is almost impossible to ensure the insulation between the metal region 14 and the metal plug 13 by substantially decreasing the width of the metal plug 13. Accordingly, short circuiting occurs easily and causes the failure of the elements.

### SUMMARY OF THE INVENTION

The present invention provides a metal interconnect structure. The metal interconnect structure solves the problems such as short circuiting and element failure caused by the continuing shrinkage of the critical dimension and ensures the proper insulation between metal interconnects and elements.

The present invention provides a metal interconnect structure, including a plurality of first plugs adjacent to each other, a first metal line extending in a first direction and contacting each first plug to form a first section with a tapered second section in between, and a second plug adjacent to the second section, both in a second direction normal to the first direction.

Because the second section between the first sections is tapered, the tapered shape maintains a sufficient distance and the required insulation between the second plug and the second section even though the second section is adjacent to the second plug. When the critical dimension of the metal interconnect structure decreases, the sufficient distance between the second plug and the second section ensures the insulation between the metal interconnect structure and the elements, so the problems such as short circuiting and failure can be avoided due to smaller critical dimension and possible technical misalignment, and the metal interconnect structure may secure its place in the next generation of smaller and smaller critical dimension.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the layout of the metal interconnect structure in the DRAM of the prior art.

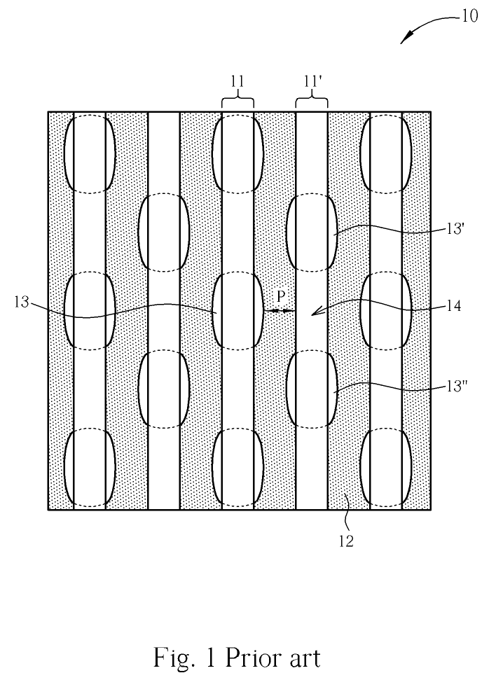

FIG. 2 illustrates a layout of the metal interconnect structure of the DRAM of the present invention.

FIG. 3 illustrates a design pattern for the metal interconnect structure of the DRAM of the present invention.

### DETAILED DESCRIPTION

The present invention relates to a metal interconnect structure with tapered sections. It is especially suitable for the high density DRAM with multiple parallel dense word-lines or bit-line arrays. Due to the tapered sections, any metal line in the metal interconnect structure of the present invention will keep a proper insulation pitch to the plug under the neighboring metal lines. Therefore, problems such as short circuiting and failure can be avoided because of smaller critical dimension.

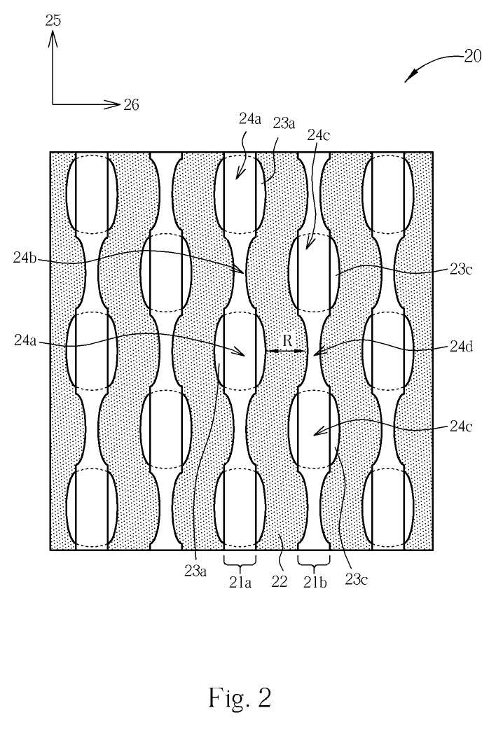

FIG. 2 illustrates a layout of the metal interconnect structure of the DRAM of the present invention. As shown in FIG. 2, there are a plurality of parallel metal interconnects, such as 21a and 21b, in the layout 20 of the metal interconnect structure of the DRAM of the present invention. An insulation 22 is formed in between to avoid short circuiting. The metal section 24a which is on the metal interconnect 21a and directly contacts the metal plug 23a usually serves as the electrical connection of the source or drain underneath (not shown). The metal section 24b is between the metal sections 24a. In order to decrease the resistance, the width of the metal plugs is usually greater than that of the metal interconnects. Similarly, there are metal sections 24c directly contacting the metal plug 23c and the metal section 24d between the metal sections 24c on another neighboring metal interconnect 21b and the distance between the metal section 24d and the metal plug 23a is R.

For serving as an electrical connection, the metal plug 23a and 23c each includes a conductive material, such as W. For the purpose of layout, the metal plugs 23a are disposed at an interval of a proper distance, so that the metal section 24a and the metal section 24b are disposed on the metal interconnect 21a in alternate order. Other metal interconnects, such as the metal interconnect 21b, may be arranged similarly. The second metal plug 23c are usually disposed at an interval of a proper distance.

The insulation layer 22 can separate the metal interconnect 21a from another neighboring metal interconnect 21b to avoid short circuiting. In other words, the metal plug 23a and 23c are all disposed in the insulation layer 22.

The metal section 24b on the metal interconnect 21a neighboring the metal plug 23c is tapered, preferably in a shape of an hourglass, shown in FIG. 2, to maintain the electrical insulation between the metal plug 23c and the metal interconnect 21a. Similarly, the metal section 24d on the metal interconnect 21b parallel with the metal interconnect 21a is also tapered. Preferably, the tapered metal sections are disposed on the insulation layer 22.

The tapered shape with two wider ends and a narrower middle may keep a proper distance to the neighboring metal plugs with greater width. For example, the pitch between the metal section 24b and the metal plug 23c and the pitch between the metal plug 23a and the metal section 24d are all about R.

The metal section 24a and the metal section 24b are on the metal interconnect 21a extending along the first direction 25. The metal plug 23c near the metal section 24b along with the metal section 24b are on a second direction 26, as shown in FIG. 2. Generally speaking, the first direction is not parallel with the second direction. Preferably, the first direction is roughly normal to the second direction.

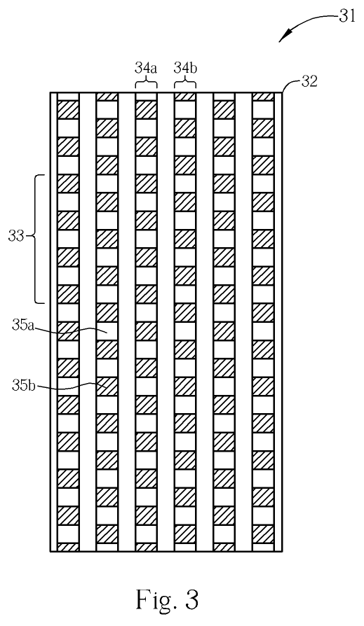

To form the layout of the metal interconnect structure of the DRAM of the present invention, it takes a special pattern. As shown in FIG. 3, it illustrates a design pattern for the metal interconnect structure of the DRAM of the present invention. As shown in FIG. 3, the reticle 31 includes a glass substrate 32 and a pattern 33 on the surface of the glass substrate 32. The pattern 33 includes a plurality of lines, 34a/34b for example, a transparent region 35a and a shielded region 35b covered by a metal layer 36 thereon. Generally speaking, the glass substrate 32 is usually made of quartz so as to have high transmission to the light source. The function of the metal layer 36 is on one hand to block the light so as to form a pre-determined pattern on the photoresist, and on the other hand to be easy to be patterned by etching. Accordingly, the metal layer 36 usually includes Cr or other suitable metal materials.

The pattern 33 on the surface of the glass substrate 32 defines the metal interconnect structure of the DRAM of the present invention. It usually includes a plurality of parallel lines, 34a/34b for example. The transparent region 35a and the shielded region 35b are usually disposed in alternate order laterally and longitudinally to define the pattern 33, as shown in FIG. 3. The metal interconnect structure of the DRAM of the present invention is formed after the transfer of the pattern 33 on the reticle 31 is completed.

Because the metal sections on one metal interconnect and on another neighboring metal interconnect are all tapered, the tapered shape maintains a sufficient insulation distance between the metal plugs and the metal sections even though they are adjacent to each other. When the critical dimension of the metal interconnect structure decreases, the sufficient distance between the second plug and the second section ensures the insulation between the metal interconnect structure and the elements, so the problems such as short circuiting and failure can be avoided due to smaller critical dimension and possible technical misalignment, and the metal interconnect structure may secure its place in the next generation of smaller and smaller critical dimension.

Those skilled in the art will readily observe that numerous modifications and alterations of the device and method may be made while retaining the teachings of the invention.

What is claimed is:

1. A metal interconnect structure comprising:
a plurality of first plugs adjacent to each other;
a first metal line extending in a first direction and contacting each said first plug to form a first section with a second section in between, wherein the second section is in a shape of an hourglass; and
a second plug adjacent to said second section, both said second plug and said second section in a second direction normal to said first direction.

2. The metal interconnect structure of claim 1, wherein said first plug comprises a conductive material.

3. The metal interconnect structure of claim 1, wherein said second plug comprises a conductive material.

4. The metal interconnect structure of claim 1, wherein said first section and said second section are disposed on said first metal line in alternate order.

5. The metal interconnect structure of claim 1, wherein the width of said first plug is greater than that of said first metal line.

6. The metal interconnect structure of claim 1, wherein said second plug is electrically insulated against said second section.

7. The metal interconnect structure of claim 1, further comprising a second metal line and a plurality of second plugs, said second metal line extending in said first direction and contacting each said second plug to form a third section with a fourth section in between, wherein the fourth section is in a shape of an hourglass.

8. The metal interconnect structure of claim 7, wherein the width of said second plug is greater than that of said second metal line.

9. The metal interconnect structure of claim 7, wherein said first plug is adjacent to said fourth section and said first plug as well as said forth section are in said second direction.

10. The metal interconnect structure of claim 7, wherein the pitch between said first plug and said fourth section is substantially the same as that of said second plug and said second section.

11. The metal interconnect structure of claim 7, wherein said third section and said fourth section are disposed on said second metal line in alternate order.

12. The metal interconnect structure of claim 7, wherein said first plug and said fourth section are disposed along said second direction in alternate order.

13. The metal interconnect structure of claim 7, wherein said second plug and said second section are disposed along said second direction in alternate order.
